(19) United States
(12) Patent Application Publication
(10) Pub. No.: US 2010/0157548 A1
(43) Pub. Date: Jun. 24, 2010

(54) FOLDABLE ELECTRICAL DEVICES

(75) Inventors: Yaping Wang, Shanghai (CN); Yifeng Sun, Shanghai (CN)

Correspondence Address: MCDERMOTT WILL & EMERY LLP, 600 13TH STREET, N.W., WASHINGTON, DC, 20005-3096, US

(73) Assignees: INVENTEC APPLIANCES (SHANGHAI) CO., LTD.; INVENTEC APPLIANCES CORP.

(21) Appl. No.: 12/543,719

(22) Filed: Aug. 19, 2009

(30) Foreign Application Priority Data
Dec. 19, 2008 (CN) 200820157447.X

(51) Int. Cl. H05K 1/00

(52) U.S. Cl. 361/749

(57) ABSTRACT

A foldable electrical device (100) includes a first housing (110), a second housing (120) foldably connected to the first housing, and a flexible printed circuit board (140). The flexible printed circuit board includes a first portion (142), a second portion (144) and a curving portion (146) connecting the first portion and the second portion. The first portion is at least partially received within the first housing, the second portion is at least partially received within the second housing, and the curving portion winds around an axis which is substantially stationary with respect to the second housing for at least 360 degrees.

### BACKGROUND

1. Technical Field

The present teaching relates generally to foldable electrical devices. Specifically, the present teaching relates to foldable electrical devices having a flexible printed circuit board therein.

2. Discussion of Related Art

Foldable electrical devices are typical devices which have a first portion and a second portion foldably/rotatably connected to the first portion. Such foldable electrical devices could be moved to an unfolded position to facilitate the operation, and to a folded position to facilitate being carried on. Flexible Printed Circuit boards (FPCs) are wildly used in such foldable electrical devices for electrically connecting the electrical components in the first portion and the second portion.

As shown in FIG. 6, a conventional FPC 200 is generally elongated. Along the longitudinal direction, the FPC 200 is divided into a first part 210, a second part 220 and a middle part 230 connecting the first and second parts 210, 220. As illustrated in FIG. 6, the FPC 200 is preformed. Specifically, the first and second parts 210, 220 extend substantially horizontally, and the middle part 230 is formed substantially perpendicular to the first and second parts 210, 220. Two board-to-board connectors (not labeled) are respectively mounted on the first and second parts 210, 220, such that FPC 200 may electrically connect to the corresponding electrical components.

When the FPC 200 is assembled into a foldable electrical device, the first and second parts 210, 220 are respectively inserted into the first and second portions of the electrical device, and the first and second portions are rotatable with respect to each other. Generally, the middle part 230 will be bended when the electrical device moves between the folded position and the unfolded position. Shear force will be applied on the middle part 230 during such folding/unfolding movement, and the shear force changes dramatically during the folding/unfolding movement. For a component bearing the shear force, a variable shear force will cause relatively bigger damage to the component than a constant shear force.

In addition, with advances in technology, there is a need for the slim type or downsized foldable electrical devices. Since such slim type or downsized electrical devices provide much smaller space for the FPC 200 received therein, the FPC 200 is apt to rub against the inner wall of the housing of the electrical device during the folding/unfolding movement. In addition, a smaller bending radius of the bended middle part 230 is required for the folding/unfolding movement of the slim type or downsized electrical devices, such that a higher shear force will be applied on the FPC 200. Such rubbing activity and/or shear force may considerably shorten the service life of the FPC 200, and may further lead to the malfunction of the electrical devices using the FPC 200 after a certain amount of folding/unfolding movement.

### BRIEF DESCRIPTION OF THE DRAWINGS

FIG. 1 is a perspective view of an exemplary mobile phone;

FIG. 2 is a perspective view of an exemplary Flexible Printed Circuit board (FPC) before being assembled into the mobile phone shown in FIG. 1;

FIG. 3 is a cross sectional view of the FPC shown in FIG. 2.

FIG. 4 is a perspective view of the FPC when being assembled into the mobile phone;

FIG. 5 is a perspective view of the mobile phone with the outer housing partially removed; and

FIG. 6 is a perspective view of a conventional FPC.

### DETAILED DESCRIPTION

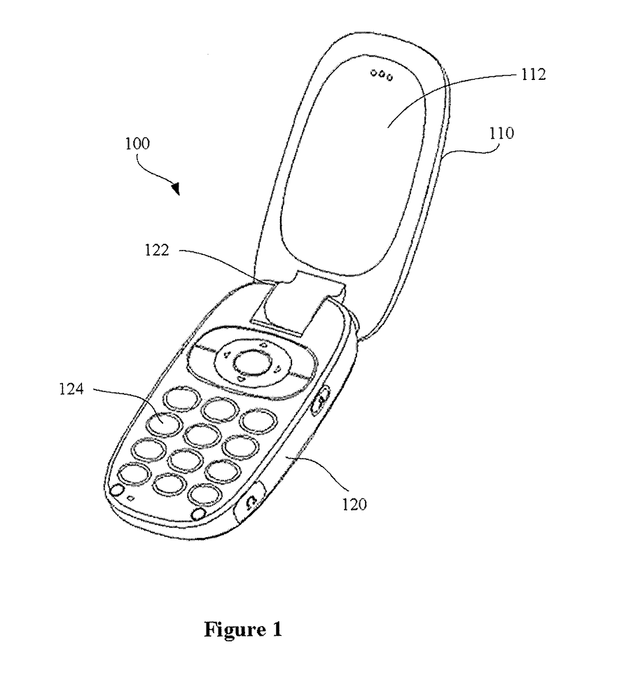

FIG. 1 is a perspective view of an exemplary mobile phone 100 in which exemplary embodiments of the present teaching may be practiced and for which the benefits of the invention may be realized. The illustrated mobile phone 100 includes an upper housing 110 and a lower housing 120. The upper housing 110 is foldably/rotatably connected to a first end 122 of the lower housing 120.

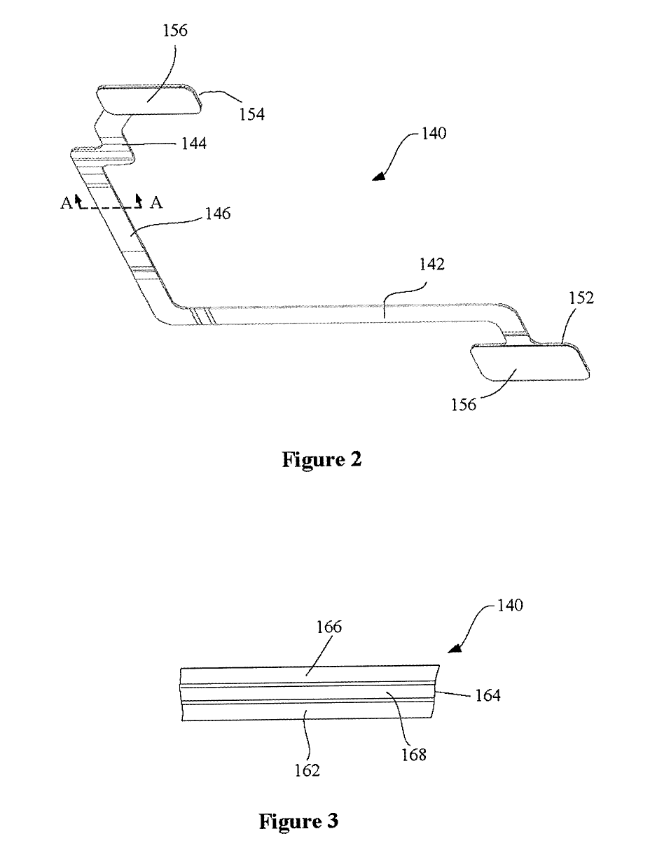

In the illustrated embodiment, a display 112 is provided on the inner side of the upper housing 110, and a keypad 124 is provided on the inner side of the lower housing 120. A hinge (not shown) may be provided in the lower housing 120 at a position adjacent to the first end 122 to facilitate the rotation of the upper housing 110 with respect to the lower housing 120. A Flexible Printed Circuit board (FPC) 140 (shown in FIG. 2) is provided in the mobile phone 100 to facilitate the operation of the mobile phone 100. In a specific embodiment, the FPC 140 is used to electrically connect the electrical components in the upper housing 110, such as for example, the display 112, with the electrical components in the lower housing 120, such as for example, the electrical sensors (not shown) associated with the keypad 124. It should be understood that, in alternative embodiments, other known electrical components, such as for example, printed circuit boards, sensors, microprocessors, microphones, headphones and cameras could also be provided in the upper housing and/or the lower housing, and the FPC could be used to electrically connect with at lease some of the electrical components positioned within the upper housing and/or the lower housing.

It is appreciated that the herein described methods and apparatus may likewise be practiced in other foldable electrical devices, such as for example, notebook computers, personal digital assistants, digital cameras having a rotatable/foldable display and other electrical devices which have a part foldably/rotatably connected with another part. Therefore, the mobile phone 100 as described and illustrated herein is for illustrative purposes only, and the methods and apparatus described herein is not intended to limit to the scope of the present invention.

FIG. 2 is a perspective view of an exemplary FPC 140 applicable to the present invention before being assembled into the mobile phone 100 shown in FIG. 1. The illustrated FPC 140 includes a first portion 142, a second portion 144 and a connecting portion 146 connecting the first portion 142 and the second portion 144. The first and second portions 142 and 144 include connecting ends 152 and 154, respectively. Each connecting end 152 or 154 may further include an electrical connector, such as for example, a board-to-board connector 156 positioned thereon for electrically connecting with the electrical components in the mobile phone 100. Connecting end 154 extends laterally in a direction away from the connecting portion 146, which may facilitate winding the connecting portion 146 during the assembly of the mobile phone 100 (described in detail hereinafter).

FIG. 3 is a cross sectional view of the FPC 140 along line A-A shown in FIG. 2. In an exemplary embodiment, the FPC 140 includes a plurality of layers overlapping each other. Specifically, the plurality of layers may include two isolating protective layers 162, 166, and a conductive layer 164. The conductive layer 164 has a predetermined conductor pattern formed by etching a conductive foil 168, and is positioned between the protective layers 162 and 166. In one embodiment, the conductive foil 168 may be gold foils, copper foils or other foils made of suitable materials. In the illustrated embodiment, in a part or the whole of the connecting portion 146 (shown in FIG. 2), two or all three of the layers 162, 164 166 are unbonded or separated with respect to each other. In addition, in a part or the whole of the first and second portions 142 and 144 (shown in FIG. 2), adjacent two or all three of the layers 162, 164 and 166 are bonded to one another by a bonding material, such as for example, an adhesive. As such, the connecting portion 146 is more flexible or pliable than the first and second portions 142 and 144, which facilitate winding the connecting portion during the assembly of the mobile phone 100 (described in detail hereinafter). In an alternative embodiment, the circuit layout on the connecting portion 146 of the FPC 140 may be designed to merge some of the lines, so that there are fewer lines in the connecting portion 146, and the connecting portion 146 is thinner. As a result of that, the connecting portion 146 may be more flexible or pliable than the first and second portions 142, 144. It should be understood that the lines on the connecting portion 146 could be merged, and the layers of the connecting portion 146 could be unbonded to each other at the same time, such that the connecting portion 146 becomes more flexible or pliable.

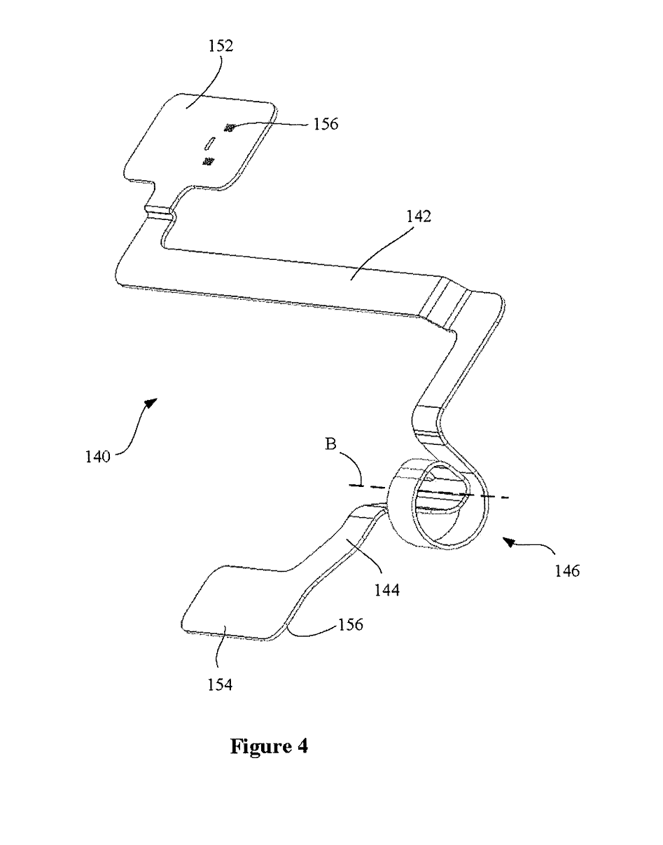

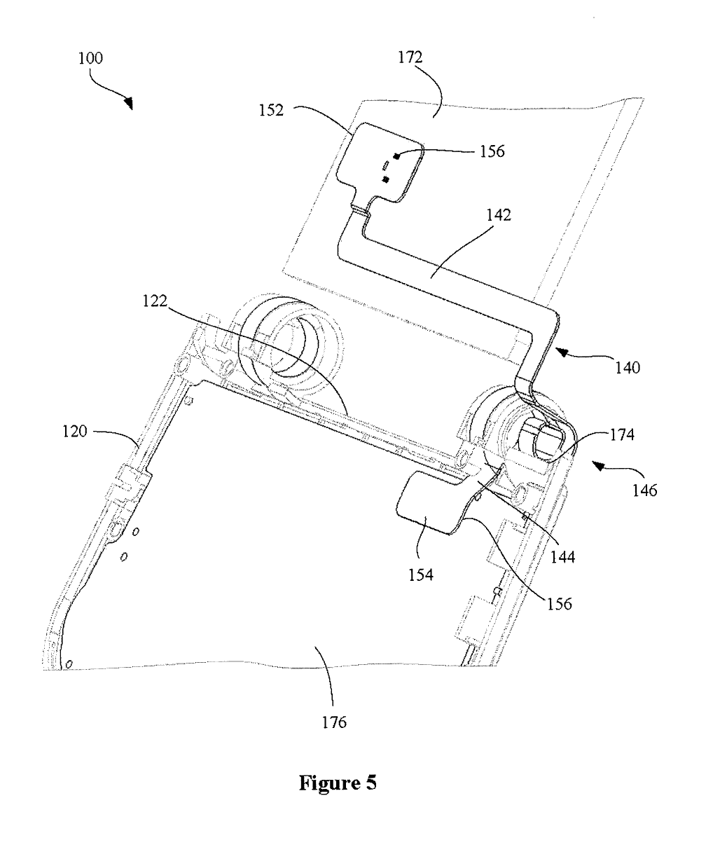

FIG. 4 is a perspective view of the FPC 140 when being assembled into the mobile phone 100, and FIG. 5 is a perspective view of the mobile phone 100 wherein the upper housing 110 (shown in FIG. 1) and a part of the lower housing 120 are removed. In an exemplary assembling process, the first portion 142 of the FPC 140 is at least partially inserted into the upper housing 110 of the mobile phone 100, and the board-to-board connector 156 is electrically connected with a printed circuit board 172 received in the upper housing 110.

The connecting portion 146 then winds around a first axis B as indicated in FIG. 4 for about 360 degrees to form a curving portion, and the curving portion 146 is received in a channel 174 defined in the lower housing 120 and adjacent the first end 122. Specifically, the connecting end 154 may be held to wind the connecting portion 146, and the first axis B may be substantially parallel to the hinge (not shown) and may be substantially stationary with respect to the lower housing 120. It should be understood that, in alternative embodiments, the curving portion 146 could be wound for more than 360 degrees and could be received in the upper housing 110.

The second portion 144 is then at least partially positioned into the lower housing 120, and the board-to-board connector 156 on the connecting end 154 is electrically connected with a printed circuit board 176 received in the lower housing 120. As such, the printed circuit boards 172 and 176 are electrically connected with each other through the FPC 140.

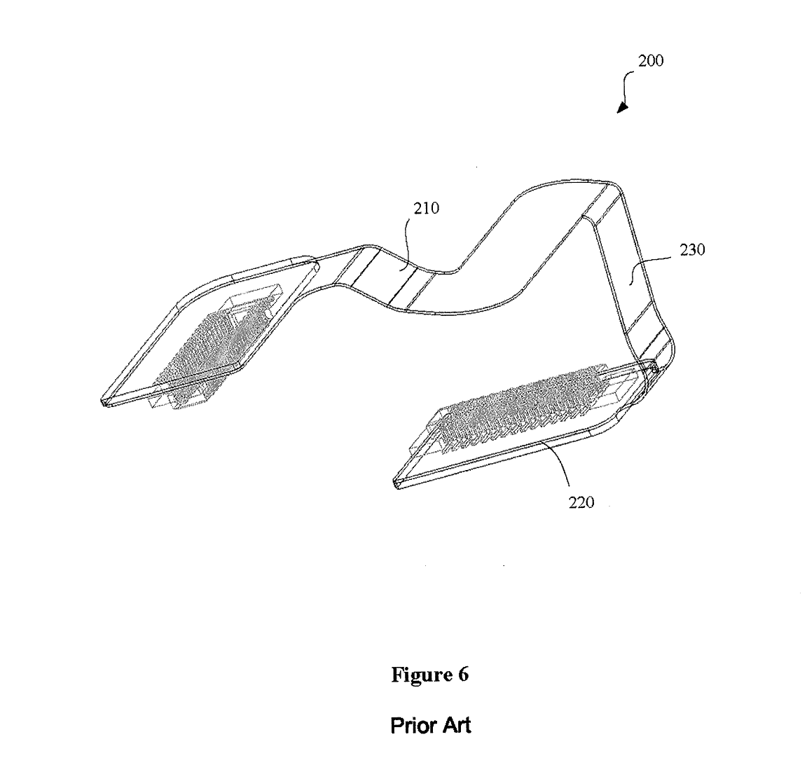

In operation, the upper housing 110 may be moved to an unfolded position (as shown in FIG. 1) to facilitate making phone calls, and may also be moved to a folded position (described herein) abutting the lower housing 120 to facilitate being carried on. During the folding/unfolding movement, the first portion 142 of the FPC 140 moves together with the upper housing 110, and the curving portion 146 expands or contracts in the lower housing 120 and is substantially free of friction with the inner surface of the channel 174. In addition, during the folding/unfolding movement, the force applied on the curving portion 146 is mainly compressive force and/or stretching force, and the shear force applied on the curving portion 146 is relatively small compared with the conventional FPC 200 (see FIG. 6). Specifically, as compared with the conventional FPC 200, the change range of the shear force applied on the curving portion 146 is much smaller during the folding/unfolding movement. In one embodiment, the shear force applied on the curving portion 146 is substantially unchanged or unaltered when the upper housing 110 rotates with respect to the lower housing 120. Therefore, the service life of the FPC 140 may be desirably enhanced.

While the inventions have been described with reference to the certain illustrated embodiments, such as the illustrated mobile phone, the words that have been used herein are words of description, rather than words of limitation. Changes may be made, within the purview of the appended claims, without departing from the scope and spirit of the invention in its aspects, such that the present invention may also applied to other electrical devices, such as for example, notebook computers, digital cameras and personal digital assistants. Although the inventions have been described herein with reference to particular structures, acts, and materials, the invention is not to be limited to the particulars disclosed, but rather can be embodied in a wide variety of forms, some of which may be quite different from those of the disclosed embodiments, and extends to all equivalent structures, acts, and, materials, such as are within the scope of the appended claims.

We claim:

1. A foldable electrical device, comprising:
a first housing;
a second housing foldably connected to the first housing; and
a flexible printed circuit board comprising a first portion, a second portion and a curving portion connecting the first portion and the second portion, wherein the first portion is at least partially received within the first housing, the second portion is at least partially received within the second housing, and the curving portion winds around a first axis for at least 360 degrees.

2. The foldable electrical device according to claim 1, wherein the curving portion is more pliable than the first portion and the second portion.

3. The foldable electrical device according to claim 2, wherein the flexible printed circuit board comprise a plurality of layers, and at least two adjacent layers of the plurality of layers are separated from each other in the curving portion.

4. The foldable electrical device according to claim 3, wherein the plurality of layers comprises a conductive layer and two protective layers, and the conductive layer and the protective layers are unbonded to each other in the curving portion.

5. The foldable electrical device according to claim 3, wherein the at least two adjacent layers are bonded to each other in at least a part of at least one of the first portion and the second portion.

6. The foldable electrical device according to claim 1, wherein the second housing comprises a channel defined therein, the channel is configured to receive at least a part of the flexible printed circuit board, and the curving portion is configured to be substantially free of friction with the channel when the first housing rotates with respect to the second housing.

7. The foldable electrical device according to claim 1, wherein the shear force applied on the curving portion is configured to be substantially unchanged when the first housing rotates with respect to the second housing.

8. The foldable electrical device according to claim 1, wherein the second portion further comprises a connecting end extending away from the curving portion, and the connecting end is configured to electrically connect with an electrical component.

9. A flexible printed circuit board for use in an electrical device, the electrical device including a first housing and a second housing foldably connected to the first housing, the flexible printed circuit board comprising:
a first portion configured to be at least partially received in a first housing;
a second portion configured to be at least partially received in a second housing; and
a connecting portion connecting the first portion and the second portion, wherein the connecting portion is configured to wind around a first axis for at least 360 degrees when being received in an electrical device.

10. The flexible printed circuit board according to claim 9, wherein the connecting portion is more flexible than the first portion and the second portion.

11. The flexible printed circuit board according to claim 10, further comprising a plurality of layers, wherein at least two adjacent layers of the plurality of layers are separated from each other in the connecting portion.

12. The flexible printed circuit board according to claim 11, wherein the plurality of layers comprises a conductive layer and two protective layers, and the conductive layer and the protective layers are separated from each other in the connecting portion.

13. The flexible printed circuit board according to claim 11, wherein the at least two adjacent layers are bonded to each other in at least a part of at least one of the first portion and the second portion.

14. The flexible printed circuit board according to claim 9, wherein the connecting portion is configured to be at least partially received in a channel defined within the second housing, and the connecting portion is configured to be substantially free of friction with the inner surface of the channel when the first housing rotates with respect to the second housing.

15. The flexible printed circuit board according to claim 9, wherein the shear force applied on the connecting portion is configured to be substantially unaltered when the first housing rotates with respect to the second housing.

16. The flexible printed circuit board according to claim 9, wherein the second portion further comprises a connecting end extending away from the connecting portion, and the connecting end is configured to electrically connect with an electrical component.

17. A foldable electrical device, comprising:
a first housing;
a second housing rotatably connected to the first housing; and
a printed circuit board comprising a first portion, a second portion and a flexible curving portion connecting the first portion and the second portion, wherein the first portion is at least partially received within the first housing, the second portion is at least partially received within the second housing, and the curving portion winds around a first axis for about 360 degrees.

18. The foldable electrical device according to claim 17, wherein the curving portion is more flexible than the first portion and the second portion.

19. The foldable electrical device according to claim 18, wherein the printed circuit board is a flexible printed circuit board, the printed circuit board comprise a plurality of layers, and at least two adjacent layers of the plurality of layers are unfixed to each other in the curving portion.

20. The foldable electrical device according to claim 19, wherein the plurality of layers comprises a conductive layer and two protective layers, and the conductive layer and the protective layers are unbonded to each other in the curving portion.
